(19) United States
(12) Patent Application Publication
(10) Pub. No.: US 2016/0329358 A1
(43) Pub. Date: Nov. 10, 2016

(54) PIXEL STRUCTURE

(71) Applicant: Au Optronics Corporation, Hsinchu (TW)

(72) Inventors: Ming-Huei Wu, Yilan County (TW); Kun-Cheng Tien, New Taipei City (TW); Shin-Mei Gong, Taoyuan County (TW); Jen-Yang Chung, Penghu County (TW); Wei-Chun Wei, Taipei City (TW); Cheng Wang, Yilan County (TW); Chien-Huang Liao, Hsinchu City (TW); Wen-Hao Hsu, Hsinchu County (TW)

(21) Appl. No.: 15/215,574

(22) Filed: Jul. 20, 2016

Related U.S. Application Data
(63) Continuation of application No. 13/932,019, filed on Jul. 1, 2013.

(30) Foreign Application Priority Data
Apr. 12, 2013 (TW) 102113069

(51) Int. Cl. H01L 27/12

(52) U.S. Cl. CPC H01L 27/1255; H01L 27/124

(57) ABSTRACT

A pixel structure includes a first conductive layer, a stacked layer, and a third conductive layer. The first conductive layer includes a first gate, a first scan line connected to the first gate, and a capacitor electrode separated from the first scan line. The stacked layer includes a semiconductor layer and a second conductive layer. The second conductive layer includes a data line, a first source connected to the data line, a second source, a first drain, a second drain, a connecting electrode connected to the second source and electrically connected to the first drain, and a coupling electrode connected to the second drain. The third conductive layer includes a first pixel electrode connected to the first drain, a second pixel electrode electrically connected to the connecting electrode, a first extending portion, and a second extending portion.

### CROSS-REFERENCE TO RELATED APPLICATION

This application is a continuation application of and claims the priority benefit of a prior application Ser. No. 13/932,019, filed on Jul. 1, 2013, now pending. The prior application Ser. No. 13/932,019 claims the priority benefit of Taiwan application serial no. 102113069, filed on Apr. 12, 2013. The entirety of each of the above-mentioned patent applications is hereby incorporated by reference herein and made a part of this specification.

### BACKGROUND

1. Technical Field

The disclosure relates to a pixel structure. More particularly, the disclosure relates to a pixel structure capable of mitigating an image sticking display effect.

2. Description of Related Art

Generally, a pixel structure of a display panel may include a scan line, a data line, a pixel electrode, and a storage capacitor. In a case that a semiconductor layer is located below an upper electrode of the storage capacitor, the storage capacitor that should have been constituted by stacking the upper electrode and the lower electrode turns to be constituted by coupling the semiconductor layer to the lower electrode of the storage capacitor. Besides, the intersection of the scan line and the data line may encounter the same issue as that occurs in the storage capacitor, and thus a relatively large parasitic capacitance may be generated. When the semiconductor layer is subject to a voltage, the problem of accumulation of charges, current leakage of the insulation layer, or lateral migration of negative charges is likely to occur. Therefore, if the upper and lower electrodes of any capacitor are formed respectively by the semiconductor layer and a conductive material coupling to each other, the capacitance can be hardly estimated, and an image sticking defect is likely to be caused.

### SUMMARY

The disclosure is directed to a pixel structure capable of mitigating an image sticking display effect.

In an embodiment of the disclosure, a pixel structure is provided. The pixel structure includes a first conductive layer, a stacked layer including a semiconductor layer and a second conductive layer stacked on the semiconductor layer, and a third conductive layer. The first conductive layer is located on a substrate and includes a first gate, a second gate, a first scan line, and a capacitor electrode. The first gate is connected to the first scan line, and the first scan line is separated from the capacitor electrode. The stacked layer is located on the substrate. The second conductive layer includes a data line, a first source, a second source, a first drain, a second drain, a connecting electrode, and a coupling electrode. The first source is connected to the data line. The connecting electrode is connected to the second source and electrically connected to the first drain. The second drain is connected to the coupling electrode. The third conductive layer is located on the substrate and includes a first pixel electrode, a second pixel electrode, a first extending portion, and a second extending portion. The first pixel electrode is connected to the first drain. The second pixel electrode is electrically connected to the connecting electrode. The first extending portion is connected to the first pixel electrode and overlapped with one portion of the coupling electrode; the second extending portion is connected to the capacitor electrode and overlapped with another portion of the coupling electrode.

In view of the above, the storage capacitor in the pixel structure as described herein is formed due to the electrical coupling between the second conductive layer and the third conductive layer; hence, the storage capacitor in the pixel structure is not apt to be affected by the electrical change of the semiconductor layer. As such, when the pixel structure described herein is applied to display images, the image sticking problem is less likely to occur.

To make the above features and advantages of the disclosure more comprehensible, several embodiments accompanied with drawings are described in detail as follows.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1A is a schematic top view illustrating a pixel structure according to a first embodiment of the disclosure.

FIG. 1B is a schematic cross-sectional schematic view taken along a section line A-A′ depicted in FIG. 1A.

FIG. 1C is a schematic cross-sectional view taken along a section line B-B′ depicted in FIG. 1A.

FIG. 2 is a schematic top view illustrating a pixel structure according to a second embodiment of the disclosure.

FIG. 3A is a schematic top view illustrating a pixel structure according to a third embodiment of the disclosure.

FIG. 3B is a schematic cross-sectional schematic view taken along a section line C-C′ depicted in FIG. 3A.

FIG. 4 is a schematic top view illustrating a pixel structure according to a fourth embodiment of the disclosure.

### DETAILED DESCRIPTION OF DISCLOSED EMBODIMENTS

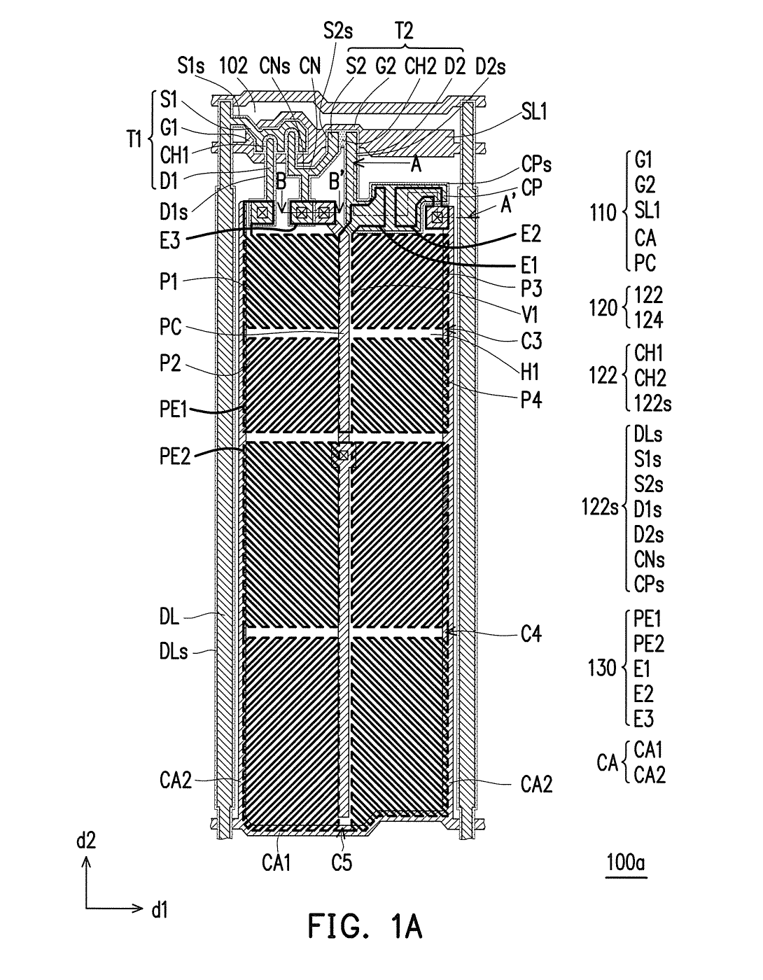

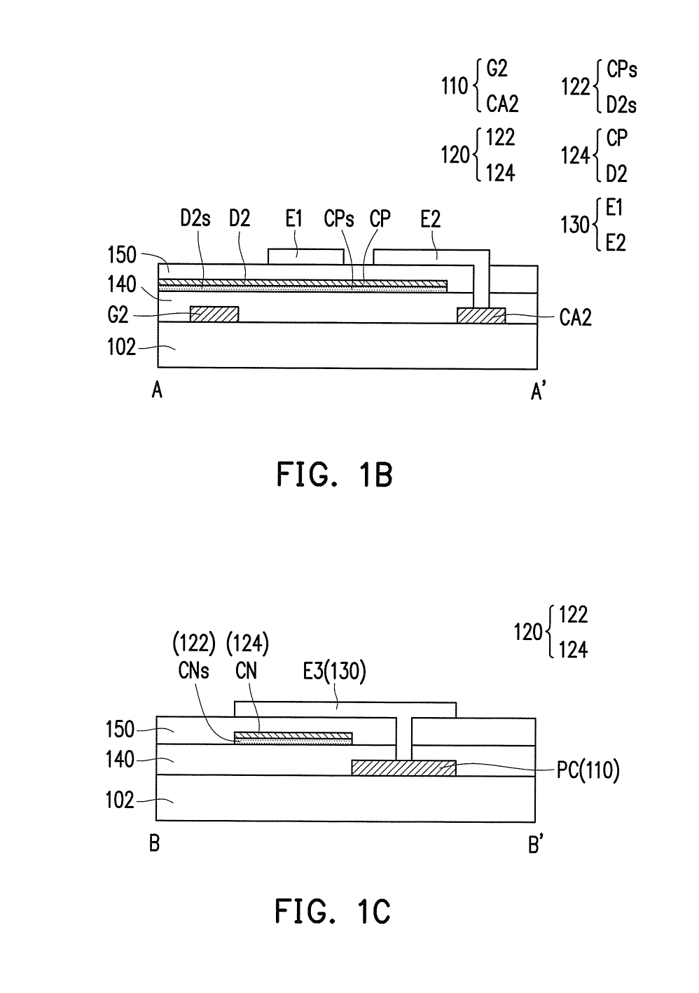

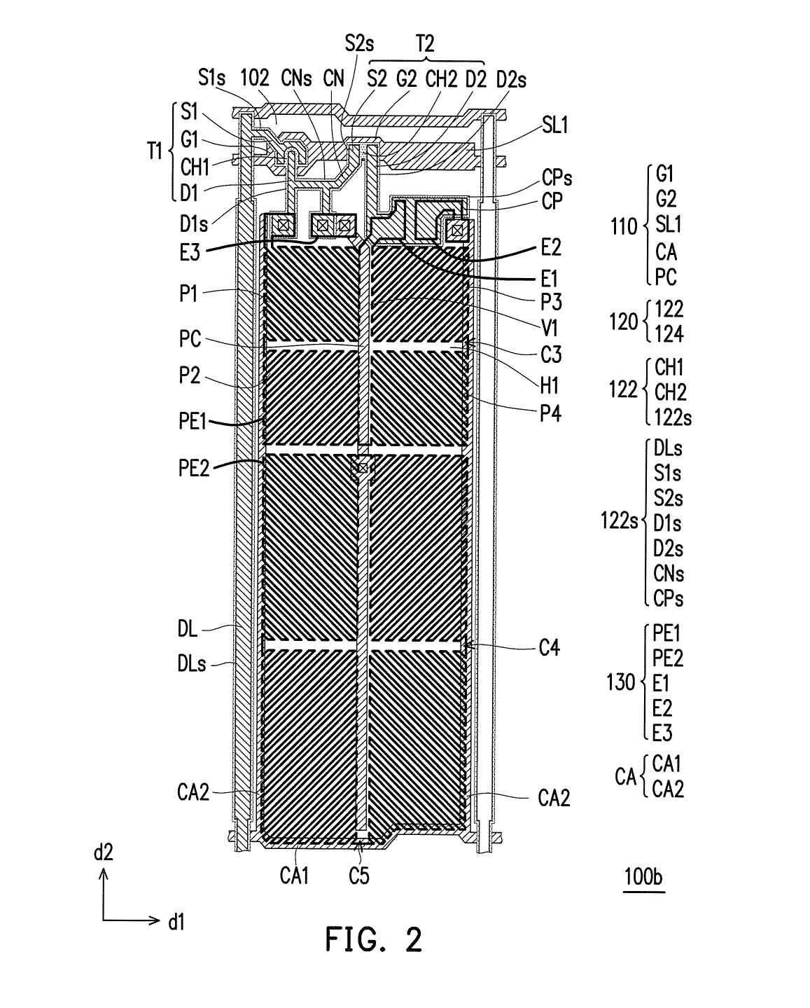

FIG. 1A is a schematic top view illustrating a pixel structure according to a first embodiment of the disclosure. FIG. 1B is a schematic cross-sectional schematic view taken along a section line A-A′ depicted in FIG. 1A. FIG. 1C is a schematic cross-sectional view taken along a section line B-B′ depicted in FIG. 1A. With reference to FIG. 1A, FIG. 1B, and FIG. 1C, the pixel structure 100a includes a first conductive layer 110, a stacked layer 120 formed by stacking a semiconductor layer 122 and a second conductive layer 124 together, and a third conductive layer 130.

The first conductive layer 110 is located on a substrate 102. Besides, the first conductive layer 110 includes a first gate G1, a second gate G2, a first scan line SL1, and a capacitor electrode CA. The first gate G1 is connected to the first scan line SL1. The second gate G2 is also connected to the first scan line SL1. The first scan line SL1 is extended along a first direction d1, and the first scan line SL1 and the capacitor electrode CA are separated from each other. The shaped of the capacitor electrode CA is similar to a U-shaped or U-liked shape. The first conductive layer 110 may be made of a metallic material; however, the disclosure is not limited thereto, and the first conductive layer 110 in other embodiments of the disclosure may be made of other conductive materials, such as alloy, metal nitride, metal oxide, metal oxynitride, an organic conductive material, or a combination of at least two of the above-mentioned materials.

Specifically, the capacitor electrode CA mainly includes a connecting portion CA1 and two branches CA2, and extension directions of the branches CA2 are different from that of the connecting portion CA1. The connecting portion CA1 is substantially extended along the first direction d1, and thus the extension direction of the connecting portion CA1 is substantially the same as that of the first scan line SL1, which should however not be construed as a limitation to the disclosure. The two branches CA2 are substantially extended in a second direction d2, and the first direction d1 is different from the second direction d2, so as to form a pattern that has a U shape or a U-like shape. In this embodiment, the first direction d1 and the second direction d2 are, for instance, substantially perpendicular to each other, whereas the disclosure is not limited thereto. The opening of the U-shaped pattern faces the first scan line SL1 in the same pixel structure 100a.

The stacked layer 120 is located on the substrate 102. Here, the stacked layer 120 includes the semiconductor layer 122 and the second conductive layer 124. The second conductive layer 124 is stacked on the semiconductor layer 122; that is, the semiconductor layer 122 is located between the first conductive layer 110 and the second conductive layer 120. The semiconductor layer 122 may be made of amorphous silicon, monocrystalline silicon, polysilicon, microcrystalline silicon, an oxide semiconductor, an organic semiconductor, any other appropriate semiconductor material, or a combination of at least two of the above-mentioned materials. The second conductive layer 124 may be made of a metallic material; however, the disclosure is not limited thereto, and the second conductive layer 124 in other embodiments of the disclosure may be made of other conductive materials, such as alloy, metal nitride, metal oxide, metal oxynitride, an organic conductive material, or a combination of at least two of the above-mentioned materials.

The second conductive layer 124 includes a data line DL, a first source SI, a second source S2, a first drain D1, a second drain D2, a connecting electrode CN, and a coupling electrode CP. The first source S1 is connected to the data line DL. The connecting electrode CN is connected to the second source S2 and electrically connected to the first drain D1. The second drain D2 is connected to the coupling electrode CP. The first source S1 and the first drain D1 are separated from each other; the second source S2 and the second drain D2 are separated from each other; the first source S1 and the second drain D2 are separated from each other.

In the present embodiment, the semiconductor layer 122 and the second conductive layer 124 are preferably formed with use of the same photomask; therefore, the boundaries and the profiles of the semiconductor layer 122 and the second conductive layer 124 are similar, and the semiconductor layer 122 is in direct physical contact with the second conductive layer 124. In other words, the semiconductor layer 122 is located below the second conductive layer 124. For instance, the semiconductor layer 122 includes a first channel pattern CH1, a second channel pattern CH2, and a lower pattern 122s. The lower pattern 122s includes a lower data line DLs, a lower first source S1s, a lower second source S2s, a lower first drain D1s, a lower second drain D2s, a lower connecting electrode CNs, and a lower coupling electrode CPs.

The data line DL, the first source S1, the second source S2, the first drain D1, the second drain D2, the connecting electrode CN, and the coupling electrode CP of the second conductive layer 124 are stacked onto the lower data line DLs, the lower first source S1s, the lower second source S2s, the lower first drain D1s, the lower second drain D2s, the lower connecting electrode CNs, and the lower coupling electrode CPs of the semiconductor layer 122. Hence, the lower first source S1s is connected to the lower data line DLs. The first channel pattern CH1 is located between the lower first source S1s and the lower first drain D1s. The second channel pattern CH2 is located between the lower second source S2s and the lower second drain D2s. The lower connecting electrode CNs is connected to the lower second source S2s and electrically connected to the lower first drain D1s. The lower second drain D2s is connected to the lower coupling electrode CPs.

The third conductive layer 130 is located on the substrate 102. Here, the third conductive layer 130 includes a first pixel electrode PE1, a second pixel electrode PE2, a first extending portion E1, and a second extending portion E2. A material of the third conductive layer 130 includes indium tin oxide (ITO), indium zinc oxide (IZO), a transparent organic conductive material, any other appropriate transparent conductive material, any other appropriate conductive material, or a combination of at least two of the above-mentioned conductive materials. In the same pixel structure 100a, the first pixel electrode PE1 and the second pixel electrode PE2 are separated from each other.

The pattern design of the first and second pixel electrodes PE1 and PE2 allows the pixel structure 100a to have a plurality of alignment areas, e.g., eight alignment areas, which should not be construed as a limitation to the disclosure. For instance, the first pixel electrode PE1 includes at least one first portion (or namely first main portion, or first main truck) V1, at least one second portion (or namely second main portion, or second main truck) H1, a plurality of first beveled portions (or namely first slanted portion, or first oblique portion) P1, a plurality of second beveled portions (or namely second slanted portion, or second oblique portion) P2, a plurality of third beveled portions (or namely third slanted portion, or third oblique portion) P3, and a plurality of fourth beveled portions (or namely fourth slanted portion, or fourth oblique portion) P4. A slit exists between every two adjacent first beveled portions P1; a slit (it's not marked in figure) exists between every two adjacent second beveled portions P2; a slit (it's not marked in figure) exists between every two adjacent third beveled portions P3; a slit (it's not marked in figure) exists between every two adjacent fourth beveled portions P4. The first portion V1 and the second portion H1 may be connected to form a crisscross, for instance, so as to define four alignment areas, which respectively is disposed with the first, second, third, and fourth beveled portions P1, P2, P3, and P4 and the first, second, third, and fourth beveled portions P1, P2, P3, and P4 respectively extending toward certain alignment directions. That is, the first, second, third, and fourth beveled portions P1, P2, P3, and P4 respectively extend along one of the four different alignment directions, so as to define four alignment areas. Similarly, the second pixel electrode PE2 may employ the same pattern design to define other four alignment areas; alternatively, the second pixel electrode PE2 may have other pattern design and define more or less than four alignment areas. In addition, the embodiment depicted in FIG. 1A is merely exemplary and should by no means limit the scope of the disclosure. According to other embodiments, the capabilities of aligning the liquid crystals in the liquid crystal layer may be achieved by means of alignment protrusions or other electrode patterns instead of the pattern design of the first pixel electrode PE1 and the second pixel electrode PE2. The above slits may each have a straight-line shape, a triangular shape, a quadrangular shape, a trapezoid shape, a rhombus-like shape, a curve-like shape, an arc-like shape, a circular shape, an elliptic shape, a polygonal shape, any other appropriate shape, or a combination of at least two of the above-mentioned shapes.

The first pixel electrode PE1 is connected to the first drain D1. The second pixel electrode PE2 is electrically connected to the connecting electrode CN. The first extending portion E1 is connected to the first pixel electrode PE1 and overlapped with one portion of the coupling electrode CP. The second extending portion E2 is connected to the branches CA2 of the capacitor electrode CA and overlapped with another portion of the coupling electrode CP. In single one pixel structure, the second extending portion E2 and the first extending portion E1 are separated from each other, as shown in FIG. 1B. Besides, in FIG. 1A, the first pixel electrode PE1 and the second pixel electrode PE2 are surrounded by the capacitor electrode CA which has a U-shaped layout and are partially overlapped with the capacitor electrode CA.

The pixel structure 100a further includes a first insulation layer 140 and a second insulation layer 150. The first insulation layer 140 is located between the first conductive layer 110 and the semiconductor layer 122, and the second insulation layer 150 is located between the second conductive layer 124 and the third conductive layer 130. The semiconductor layer 122 is located between the second conductive layer 124 and the first insulation layer 140, and thus the second conductive layer 124 is substantially not in contact with the first insulation layer 140. The first insulation layer 140 and the second insulation layer 150 may be individually made of an inorganic dielectric material (e.g., silicon oxide, silicon nitride, silicon oxynitride, or any other appropriate inorganic dielectric material) or an organic dielectric material.

The second insulation layer 150 is sandwiched by the second conductive layer 124 and the third conductive layer 130, and therefore a capacitor may exist at the intersection or the overlapping portion of the second conductive layer 124 and the third conductive layer 130. Here, the capacitor is formed due to the electrical coupling effect that occurs between the second conductive layer 124 and the third conductive layer 130. For instance, the capacitor between the second conductive layer 124 and the third conductive layer 130 at least includes a capacitor C1 between the coupling electrode CP and the first extending portion E1 as well as a capacitor C2 between the coupling electrode CP and the second extending portion E2. Since the capacitors C1 and C2 are not formed due to the electrical coupling effect between the semiconductor layer 122 and the first conductive layer 110, the capacitances of the capacitor C1 and the capacitor C2 can be accurately estimated and are not apt to be changed together with the electrical change of the semiconductor layer 122.

Note that the branches CA2 of the capacitor electrode CA and the first pixel electrode PE1 may be partially overlapped, so as to generate a capacitor C3; the branches CA2 of the capacitor electrode CA and the second pixel electrode PE2 may be partially overlapped, so as to generate a capacitor C4; the connecting portion CA1 of the capacitor electrode CA and the second pixel electrode PE2 may be partially overlapped, so as to generate a capacitor C5. The capacitors C3, C4, and C5 may together constitute the storage capacitor required by the pixel structure 100a. Since each of the capacitors C3, C4, and C5 is constituted by two conductor layers such as the first conductor layer and third conductor layer, the capacitors C3, C4, and C5 are not subject to the electrical change of the semiconductor layer. That is, the storage capacitor that is comprised of the capacitors C3, C4, and C5 has the stable capacitance, and hence the image sticking display effect on the image frame displayed by the pixel structure 100a may be prevented. From another perspective, the capacitor electrode CA and the first scan line SL1 are located at different sides of the first pixel electrode PE1 or at different sides of the second pixel electrode PE2. Through said U-shaped layout, the connecting portion CA1 of the capacitor electrode CA is not overlapped with the lower first drain D1s, the lower connecting electrode CNs, and the lower second drain D2s, so as to lessen the image sticking effect resulting from the unstable capacitance generated when the first conductive layer 100 and the semiconductor layer 122 are overlapped.

The first gate G1, the first source S1, the first channel pattern CH1, and the first drain D1 together constitute the first thin film transistor (TFT) T1. The first drain D1 of the first TFT T1 is connected to the first pixel electrode PE1, and the first source S1 is connected to the data line DL. Besides, in the present embodiment, a portion of the connecting electrode CN is extended to the neighboring area of the first drain D1. The first source S1 correspondingly surrounds the portion of the connecting electrode CN extended to the neighboring area of the first drain D1, and the first channel pattern CH1 is further extended between the portion of the connecting electrode CN and the first source S1, such that the portion of the connecting electrode CN constitutes another drain of the first TFT T1. Namely, the first TFT T1 is substantially a double-drain TFT, which should however not be construed as a limitation to the disclosure.

Similarly, the second gate G2, the second source S2, the second channel pattern CH2, and the second drain D2 together constitute the second TFT T2. The second source S2 of the second TFT T2 is electrically connected to the second pixel electrode PE2 through the connecting electrode CN, and the second drain D2 is connected to the coupling electrode CP. The other drain of the first TFT T1 is one portion of the connecting electrode CN; therefore, in the same pixel structure (or namely in the single pixel structure), the second source S2 of the second TFT T2 is substantial electrically connected to the first TFT T1. In the present embodiment, at least one of the first TFT T1 and the second TFT T2 are bottom-gate TFTs, for instance; however, the disclosure is not limited thereto, and at least one of the first TFT T1 and the second TFT T2 may also be top-gate TFTs or any other appropriate TFTs.

According to the present embodiment, the first pixel electrode PE1 is located between the second pixel electrode PE2 and the first scan line SL1. Thus, in order to allow the second pixel electrode PE2 to be connected to the corresponding TFT, the first conductive layer 110 further includes a pixel connecting electrode PC. The pixel connecting electrode PC is connected between the second pixel electrode PE2 and the connecting electrode CN. In other words, the second pixel electrode PE2 is connected to the connecting electrode CN via (or namely through) the pixel connecting electrode PC. Here, the pixel connecting electrode PC constituted by the first conductive layer 110 is electrically connected to the connecting electrode CN constituted by the second conductive layer 124 through the third extending portion E3, for instance, and the third extending portion E3 belongs to the third conductive layer 130, as shown in FIG. 1C. Here, the third extending portion E3 is separated from the first extending portion E1 and is also separated form the second extending portion E2.

When the first scan line SL1 is enabled to turn on the first TFT T1, the first drain D1 may be electrically connected to the portion of the connecting electrode CN extended to the neighboring area of the first drain D1 through the first channel pattern CH1. Accordingly, in the present embodiment, the first drain D1 and the connecting electrode CN may be electrically connected to each other. However, the electrical connection between the first drain D1 and the connecting electrode CN should not be construed as a limitation to the disclosure.

Besides, in the present embodiment, both the first gate G1 and the second gate G2 are connected to the first scan line SL1, and the first TFT T1 and the second TFT T2 share the same scan line. When the first scan line SL1 is enabled, the signal from the data line DL is transmitted from the first source S1 of the first TFT T1 to the first drain D1 and is also written into the first pixel electrode PE1. At this time, the connecting electrode CN and the first drain D1 are electrically connected to each other through the semiconductor layer 122. Therefore, the signal from the data line DL is further transmitted from the first source S1 of the first TFT T1 to the connecting electrode CN and is further written into the second pixel electrode PE2.

When the first scan line SL1 is enabled, the second TFT T2 is turned on as well, and the electric connection between the second source S2 and the second drain D2 allows the signal on the connecting electrode CN to be written into the coupling electrode CP. That is, the signal on the connecting electrode CN is not only transmitted to the second pixel electrode PE2 but also written into the coupling electrode CP through the second TFT T2. At this time, the coupling electrode CP is electrically coupled to the first extending portion E1 that is connected to the first pixel electrode PE1 and is electrically coupled to the second extending portion E2 that is connected to the capacitor electrode CA (i.e., the capacitor C1 between the coupling electrode CP and the first extending portion E1 and the capacitor C2 between the coupling electrode CP and the second extending portion E2); hence, the signal written into the second pixel electrode PE2 and the coupling electrode CP may be different from the signal input to the first pixel electrode PE1 because of voltage sharing/distribution caused by capacitive coupling. When the first pixel electrode PE1 and the second pixel electrode PE2 have different voltage values, the pixel structure 100a may achieve favorable display effects, e.g., color washout may be reduced. Note that the voltage sharing/distribution described in this embodiment should not be construed as a limitation to the disclosure.

In order to make the disclosure more comprehensible, embodiments are described below as examples to prove that the disclosure can actually be realized. Moreover, elements/components/steps with same reference numbers represent the same or similar parts in the drawings and embodiments.

FIG. 2 is a schematic top view illustrating a pixel structure according to a second embodiment of the disclosure. With reference to FIG. 2, the pixel structure 100b is similar to the pixel structure 100a depicted in FIG. 1A, while the difference therebetween lies in that the connecting electrode CN of the pixel structure 100b is directly connected to the first drain D1, and the lower connecting electrode CNs is directly connected to the lower first drain D1s in the pixel structure 100b. That is, the connecting electrode CN is not only electrically connected to the first drain D1 but also physically, directly connected to the first drain D1.

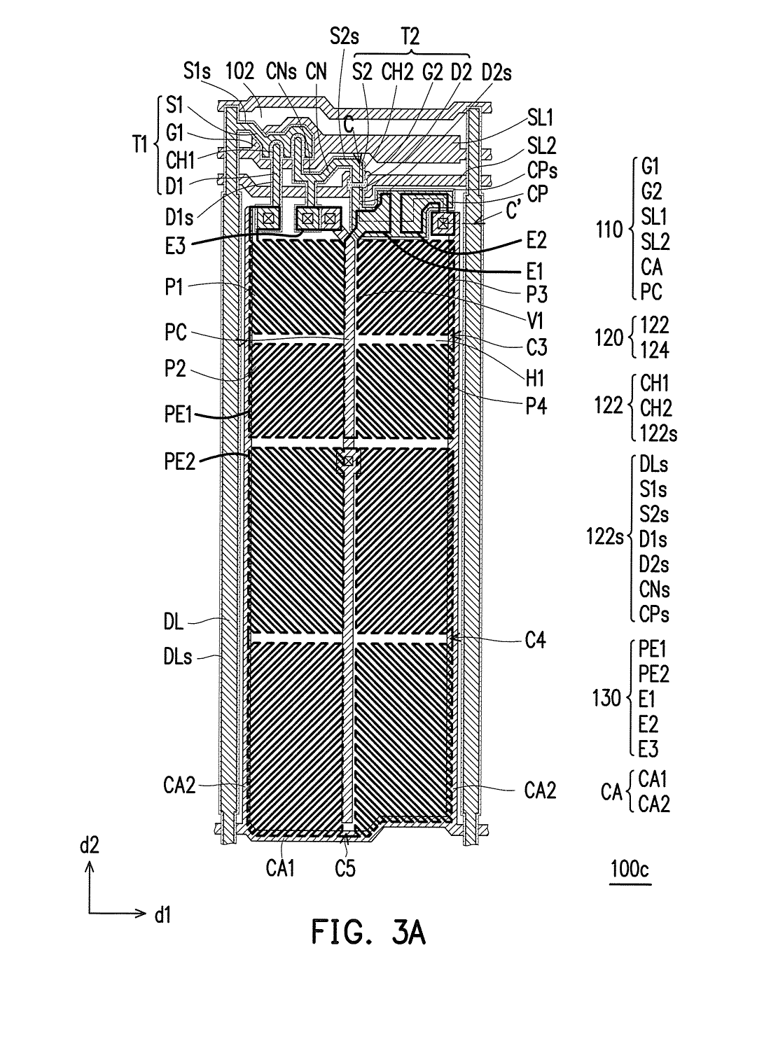

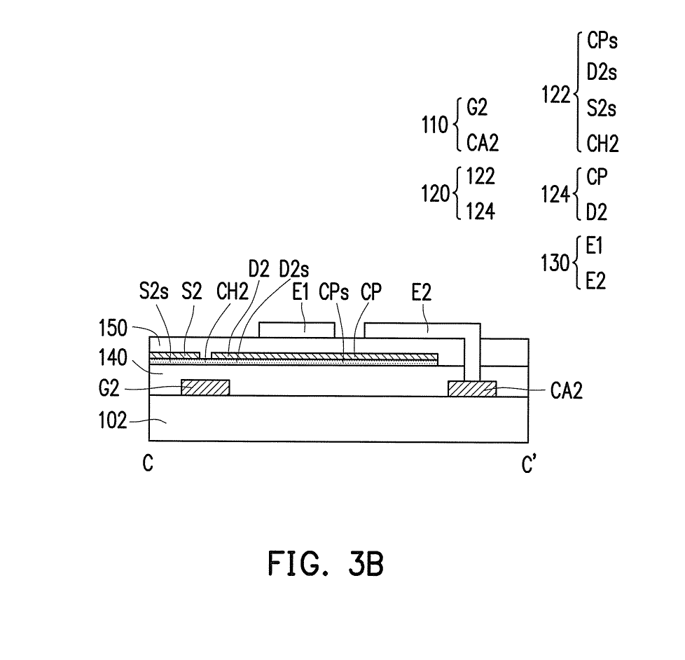

FIG. 3A is a schematic top view illustrating a pixel structure according to a third embodiment of the disclosure. FIG. 3B is a schematic cross-sectional schematic view taken along a section line C-C′ depicted in FIG. 3A. With reference to FIG. 3A and FIG. 3B, the pixel structure 100c is similar to the pixel structure 100a depicted in FIG. 1A, while the difference therebetween lies in that the first conductive layer 110 of the pixel structure 100c further includes a second scan line SL2 that is substantially extended along a first direction d1. The second scan line SL2 is separated from the first scan line SL1 and is separated from the capacitor electrode CA. In addition, the capacitor electrode CA and the second scan line SL2 are located at different sides of the first pixel electrode PE1 or at different sides of the second pixel electrode PE2.

According to the present embodiment, the first gate G1 is connected to the first scan line SL1, and the second gate G2 is connected to the second scan line SL2. Namely, the first TFT T1 and the second TFT T2 do not share the same scan line but are respectively driven by the first scan line SL1 and the second scan line SL2. When the first scan line SL1 is enabled, the signal from the data line DL is written into the first pixel electrode PE1 through the first drain D1 of the first TFT T1 and the second pixel electrode PE2 through the connecting electrode CN, respectively. At this time, the connecting electrode CN and the first drain D1 are electrically connected to each other through the semiconductor layer 122. When the second scan line SL2 is then enabled, the second drain D2 and the second source S2 may be electrically connected together by the second channel pattern CN2. Thereby, the signal written into the second pixel electrode PE2 and the connecting electrode CN from the data line DL is shared to the coupling electrode CP through the second source S2 and the second drain D2 of the second TFT T2. Due to the voltage sharing process, the potential of the second pixel electrode PE2 is changed.

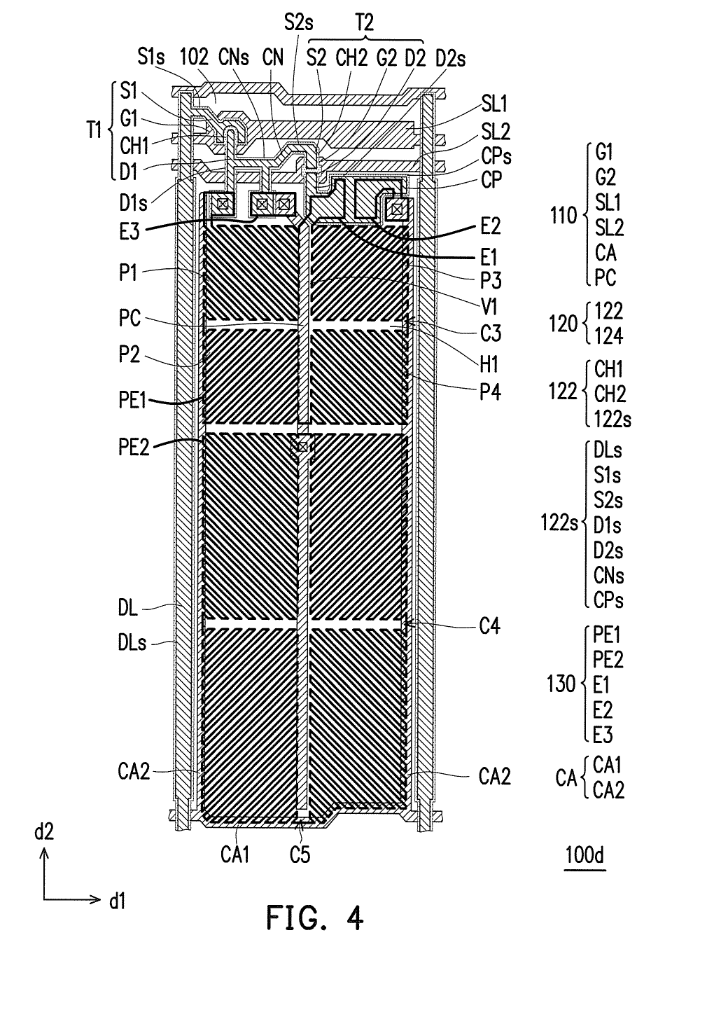

FIG. 4 is a schematic top view illustrating a pixel structure according to a fourth embodiment of the disclosure. With reference to FIG. 4, the pixel structure 100d is similar to the pixel structure 100c depicted in FIG. 3A, while the difference therebetween lies in that the connecting electrode CN of the pixel structure 100d is directly connected to the first drain D1, and the lower connecting electrode CNs is directly connected to the lower first drain D1s in the pixel structure 100d. That is, the connecting electrode CN is not only electrically connected to the first drain D1 but also physically, directly connected to the first drain D1.

To sum up, in the pixel structure as described in an embodiment of the disclosure, the storage capacitor and the capacitor associated with the coupling electrode are formed due to the electrical coupling between the second conductive layer and the third conductive layer and the electrical coupling between the first conductive layer and the third conductive layer. Additionally, the overlapping area of the first conductive layer and the semiconductor layer in the pixel structure is reduced. Hence, the capacitance of the capacitor in the pixel structure, such as the capacitance of the storage capacitor and the capacitance of the stray capacitor, can be easily estimated and is not apt to be affected by the electrical change of the semiconductor layer. As a result, the pixel structure described herein is capable of mitigating the image sticking display effect.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A pixel structure comprising:
a first conductive layer located on a surface of a substrate, the first conductive layer comprising a first gate, a second gate, a first scan line, and a capacitor electrode, the first gate being connected to the first scan line, the first scan line being separated from the capacitor electrode;
a stacked layer located on the substrate, the stacked layer comprising a semiconductor layer and a second conductive layer stacked on the semiconductor layer, the second conductive layer comprising a data line, a first source, a second source, a first drain, a second drain, a connecting electrode, and a coupling electrode, the first source being connected to the data line, the connecting electrode being directly connected to the second source and electrically connected to the first drain, the second drain being connected to the coupling electrode; and
a third conductive layer located on the substrate, the third conductive layer comprising a first pixel electrode, a second pixel electrode, a first extending electrode, and a second extending electrode, the first extending electrode is separated from the second extending electrode, the first pixel electrode being connected to the first drain, the second pixel electrode being electrically connected to the connecting electrode, the first extending electrode being connected to the first pixel electrode and overlapped with one portion of the coupling electrode in a direction perpendicular to the surface of the substrate, the second extending electrode being connected to the capacitor electrode and overlapped with another portion of the coupling electrode in the direction perpendicular to the surface of the substrate.

2. The pixel structure of claim 1, wherein the second gate is connected to the first scan line.

3. The pixel structure of claim 1, wherein the first conductive layer further comprises a second scan line, the second gate is connected to the second scan line, the second scan line is separated from the first scan line, and the second scan line is separated from the capacitor electrode.

4. The pixel structure of claim 1, wherein the first conductive layer further comprises a pixel connecting electrode, the pixel connecting electrode is adapted to connect the second pixel electrode and the connecting electrode.

5. The pixel structure of claim 1, wherein the shape of the capacitor electrode is a U shape.

6. The pixel structure of claim 1, wherein the capacitor electrode is partially overlapped with the first pixel electrode and is partially overlapped with the second pixel electrode.

7. The pixel structure of claim 1, further comprising a first insulation layer and a second insulation layer, the first insulation layer being located between the first conductive layer and the semiconductor layer, the second insulation layer being located between the second conductive layer and the third conductive layer.

8. The pixel structure of claim 1, wherein the first extending electrode being connected to the first pixel electrode is overlapped with one portion of the capacitor electrode in the direction perpendicular to the surface of the substrate.

9. The pixel structure of claim 1, wherein the second extending electrode is in direct contact with the capacitor electrode through a contact window.

10. The pixel structure of claim 1, wherein both the first pixel electrode and the second pixel electrode are disposed on a same side of the first scan line.

11. The pixel structure of claim 10, wherein the first pixel electrode and the second pixel electrode are not disposed on a different side of the first scan line.

12. The pixel structure of claim 5, wherein an opening of the U shape of the capacitor electrode is toward a same side of the first scan line in a same pixel structure.

13. The pixel structure of claim 9, wherein the capacitor electrode comprises a connecting portion and two branches, and the second extending electrode is in direct contact with one of the branches of the capacitor electrode through the contact window.

14. The pixel structure of claim 6, wherein fringes of the first pixel electrode and the second pixel electrode are located in a projection of the capacitor electrode in the direction perpendicular to the surface of the substrate.

15. The pixel structure of claim 1, wherein an end of the connecting electrode is directly connected to the second source and another end of the connecting electrode is electrically connected to the first drain.

16. The pixel structure of claim 15, wherein the another end of the connecting electrode is a third drain, and the first gate, the first source, and the third drain at least form a transistor

17. The pixel structure of claim 1, wherein an end of the connecting electrode is directly connected to the second source and another end of the connecting electrode is directly connected to the first drain.
